(19) United States
(12) Patent Application Publication
(10) Pub. No.: US 2019/0318991 A1
(43) Pub. Date: Oct. 17, 2019

(54) Output Driver Circuit Configurable with Via Layer to Support Multiple Standards

(71) Applicant: Intel Corporation, Santa Clara, CA (US)

(72) Inventors: Eah Loon Alan Chuah, Tanjung Tokong (MY); Ting Ting Au, Bayan Lepas (MY)

(21) Appl. No.: 16/456,056

(22) Filed: Jun. 28, 2019

(51) Int. Cl. H01L 23/522; H01L 23/62; H01L 23/528; H01L 21/768; H01L 21/027; H03K 17/081

(52) U.S. Cl. CPC H01L 23/5226; H01L 23/62; H01L 23/528; H03K 17/08104; H01L 21/0274; H01L 21/76877; H01L 21/76802

(57) ABSTRACT

An integrated circuit device with a single via layer, in which the via layer includes selectable via sites and/or jumpers. The selectable via sites and/or placement of jumpers may be used to configure and interconnect components and circuitry between distinct layers of multilayer circuits. In some implementations, selectively enabling via sites by filling via openings and/or using jumpers may implement a voltage-mode driver circuit with a first via configuration, a current-mode driver circuit with a second via configuration, and/or a differential driver circuit with a third configuration.

### BACKGROUND

This disclosure relates to an integrated circuit device used to support different applications by configuring via connections of a via layer.

This section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

Integrated circuit devices are used in numerous electronic systems. Computers, handheld devices, portable phones, televisions, industrial control systems, robotics, and telecommunication networking-to name just a few-all use integrated circuit devices. Integrated circuit devices may be developed using lithography techniques that pattern circuitry onto a substrate wafer that is diced to form a number of (generally identical) individual integrated circuit die. Each integrated circuit die for a particular application may include many different components, such as programmable logic fabric, digital or analog signal transmission circuitry, digital signal processing circuitry, application-specific data processing circuitry, memory, and so forth. The lithography techniques to form circuits on an integrated circuit die may involve using a variety of different steps, possibly including one or more photomasks (e.g., a photomask set) corresponding to that specific circuitry on the integrated circuit die. In other words, manufacturing an integrated circuit die that has a first functionality may involve a completely different process and/or photomask set as compared to an integrated circuit die that has a second functionality.

### BRIEF DESCRIPTION OF THE DRAWINGS

Various aspects of this disclosure may be better understood upon reading the following detailed description and upon reference to the drawings in which:

FIG. 1 is a block diagram of multiple layers of an integrated circuit device, in accordance with an embodiment of the present disclosure;

FIG. 2 is a process flow diagram of a lithography process to fabricate the integrated circuit device with a via layer for various applications, in accordance with an embodiment of the present disclosure;

FIG. 3A is a block diagram of a via layer with via connections between multiple layers of the integrated circuit device, in accordance with an embodiment of the present disclosure;

FIG. 3B is a three dimensional block diagram of the via layer of FIG. 3A, in accordance with an embodiment of the present disclosure;

FIG. 4 is a schematic diagram of a multiplexer used to dynamically configure circuitry of the integrated circuit device, in accordance with an embodiment of the present disclosure;

FIG. 5 is a schematic diagram of a via connection of the via layer used to configure circuitry of the integrated circuit device, in accordance with an embodiment of the present disclosure;

FIG. 6 illustrates a schematic diagram of configurable driver circuitry with a via layer, in accordance with an embodiment of the present disclosure;

FIG. 7 illustrates a schematic diagram of the configurable driver circuitry of FIG. 6 configured as a current-mode differential driver, in accordance with an embodiment of the present disclosure;

FIG. 8 illustrates a schematic diagram of the configurable driver circuitry of FIG. 6 configured as two independent single-ended voltage-mode drivers, in accordance with an embodiment of the present disclosure;

FIG. 9 illustrates a schematic diagram of the configurable driver circuitry of FIG. 6 configured as two independent voltage-mode single-ended drivers with voltage overstress protection, in accordance with an embodiment of the present disclosure; and

FIG. 10 illustrates a schematic diagram of the configurable driver circuitry of FIG. 6 configured as a pair of differential current-mode open drain driver, in accordance with an embodiment of the present disclosure.

### DETAILED DESCRIPTION OF SPECIFIC EMBODIMENTS

One or more specific embodiments will be described below. In an effort to provide a concise description of these embodiments, not all features of an actual implementation are described in the specification. It may be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it may be appreciated that such a development effort might be complex and time consuming, but would nevertheless be a routine undertaking of design, fabrication, and manufacture for those of ordinary skill having the benefit of this disclosure.

When introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features. Furthermore, the phrase A “based on” B is intended to mean that A is at least partially based on B. Moreover, unless expressly stated otherwise, the term “or” is intended to be inclusive (e.g., logical OR) and not exclusive (e.g., logical XOR). In other words, the phrase A “or” B is intended to mean A, B, or both A and B.

Circuitry of an integrated circuit device may be unique to the specific application for which the integrated circuit device is used. As such, the production of each integrated circuit device for a particular application may include additional and/or different fabrication steps, rendering a particular integrated circuit device designed for one application to be become inoperable or ineffective for to perform a different application function. These additional or different fabrication steps may relate to photomasks that are used to pattern circuitry for the specific application functions onto a substrate. Since the circuitry for one application function may be different than the circuitry of a different application function, the photomasks used for each of these circuitry patterns may not be used for both application functions. As will be discussed in more detail herein, producing the unique circuitry onto a substrate (e.g., wafer) during device fabrication includes the use of lithographic photomasks. Photomasks are silica plates with a pattern (e.g., circuit pattern) of opaque and transparent areas that are projected onto the substrate to define the layout of the integrated circuit. In some implementations, a set of photomasks may be used to define one or more pattern layers of a multilayered structure of the integrated circuit. In general, a photomask is placed over the substrate and short wavelength radiation (e.g., short wavelength light) is passed through to project the pattern onto the substrate surface. The patterns may guide the deposit or removal of material from the substrate.

In some implementations, integrated circuit devices include multiple layers, and often, these layers are fabricated in a sequential process. Accordingly, each of the multiple layers may be fabricated using a unique photomask or set of photomasks. As such, at least some of the photomask patterns used for a specific circuit design may be not be used for a different circuit design. Thus, producing multiple photomasks for the various integrated circuit devices and/or their multiple layers may have their own respective costs.

The integrated circuit device for a particular application may include one circuit to perform one function and another circuit to perform another function of the application. By way of example, an electronic signals transmitted on-chip between circuits or off-chip between other integrated circuits, may use different formats or standards. Each of these standards may be supported by a particular circuit and be associated with separate respective photomasks. However, the circuits for each of these different standards may include common components.

It may be desirable to maintain a single integrated circuit architecture with a driver circuit that is configurable to support each of these standards. Moreover, since a single circuit with common circuitry may be used to provide support the various standards, the overall costs of producing multiple photomasks for each circuit and/or multiple integrated circuit layers may be mitigated. To implement a configurable driver circuit in an integrated circuit device that may be configurable for various applications, a via layer may be used to connect components and circuitry between the layers of the integrated circuit device. Thus, via openings may be selectively located and formed (e.g., filled or coated with metal) on the via layer to create interconnections between the various components to implement a particular input/output (I/O) driver standard in the integrated circuit device. For example, a single circuit with a via layer may be used to configure the circuitry to implement a single-ended voltage-mode driver, a current-mode driver, and/or a true differential driver. Moreover, the circuitry may be configured to tolerate high voltage overstress, such as by using protection biasing. While this disclosure will primarily use the example of an ASIC, the systems and methods of this disclosure may apply to any suitable integrated circuit devices. For example, the methods and devices may be incorporated into numerous types of devices such as microprocessors, system on chip (SoC), or other integrated circuits. Exemplary integrated circuits include programmable array logic (PAL), programmable logic arrays (PLAs), field programmable logic arrays (FPLAs), electrically programmable logic devices (EPLDs), electrically erasable programmable logic devices (EEPLDs), logic cell arrays (LCAs), field programmable gate arrays (FPGAs), application specific standard products (ASSPs), and microprocessors, just to name a few.

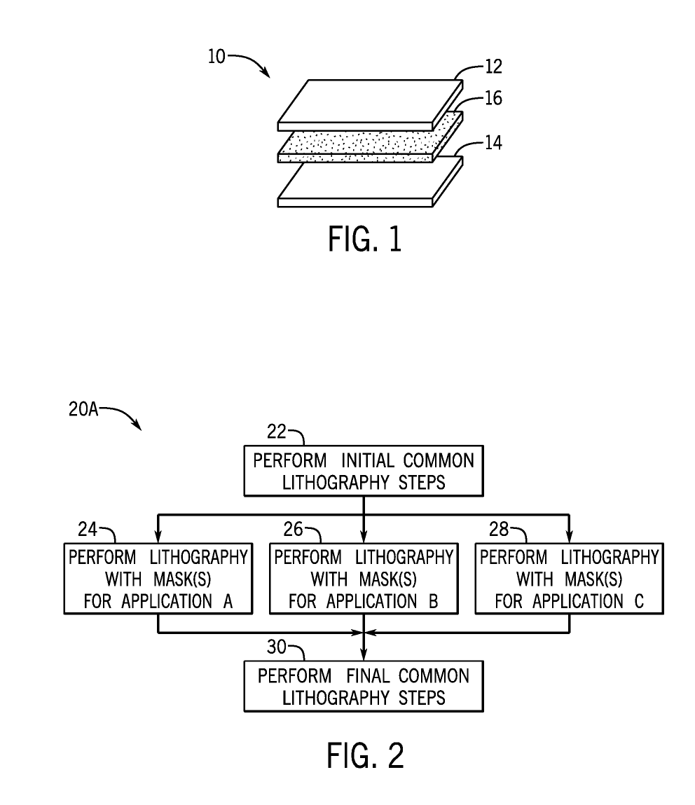

With the foregoing in mind, FIG. 1 illustrates an integrated circuit device 10 that includes multiple layers of circuitry. As shown, the integrated circuit device 10 may include a first circuit layer 12 and a second circuit layer 14. Circuit components for multiple applications (e.g., multiple I/O driver standards) may be attached or embedded to either the first circuit layer 12 and/or the second circuit layer 14 and their electrical connections may be routed on their respective first circuit layer 12 and second circuit layer 14. However, the components used for these applications are often the same components. Thus, any redundant components may unnecessarily take space on the substrates of the integrated circuit device 10. Furthermore, producing the first circuit layer 12, the second circuit layer 14, and additional layers (not shown) may each use a unique photomask or sets of photomasks, such as for each unique driver standard circuit.

The circuit layers 12 and 14 may be designed to have a variety of possible connections at a variety of possible via sites. Vias are integrated circuit structures that allow circuitry on one layer to form a connection with circuitry on another layer. Depending on the via configuration of one or more via layers 16, the circuit layers 12 and 14 may have different functionalities. Thus, many different integrated circuit devices 10 may be manufactured using the same circuit layers 12 and 14, but the different integrated circuit devices 10 may be manufactured to have different functionalities by selecting a different via configuration for the one or more via layers 16. The one or more via layers 16 may be manufactured to have a variety of different possible via configurations, where each via configuration provides different connections that determine the functionality of the layers 12 and 14, even while the layers 12 and 14 may not be changed. Thus, by manufacturing the one or more via layers 16 using a particular selected photomask or photomask set that results in a particular via configuration, a functionality of the circuit layers 12 and 14 may be controlled. It should be appreciated that, while two circuit layers 12 and 14 and one or more via layers 16 have been shown by way of example, any suitable number of circuit layers and via layers may be used. Moreover, one or more via layers may also be disposed to connect to an outer surface for selectively connecting to circuitry in a 2.5D or 3D configuration (e.g., another integrated circuit device 10, an interposer, or Embedded Multi-Die Interconnect Bridge (EMIB) by Intel Corporation®).

To illustrate, FIG. 2 shows a process flow diagram of process 20 for fabricating an integrated circuit device 10 with a particular via layer that causes the integrated circuit device 10 to selectively provide functionality for one or many different applications depending on the via configuration of the via layer. In general, the overall process 20 for fabricating integrated circuit devices 10 for each particular application includes steps of depositing, patterning, removing, and modifying electrical properties. As shown, the process may begin with performing (block 22) initial common lithography steps. These steps may include the depositing process, which includes coating or transferring photoresist material (e.g., liquid polymeric material or dry film photoresists) onto a substrate, such as a wafer. The photoresist is material that the image may be transferred to during the patterning process.

Next, the patterning step may include fabricating pattern from a photomask onto the wafer by exposing the wafer to light using the photomask. As previously discussed, photomasks are often formed from silica plates with a pattern, such as a circuit pattern, of opaque and transparent areas that are projected onto the wafer to define the layout of the integrated circuit. In some implementations, a set of photomasks may be used to define one or more pattern layers of the multilayered structure of the integrated circuit device 10. In general, the photomask is placed over the substrate and a short wavelength light is passed through to project the pattern onto the substrate surface.

While the common lithography steps of block 22 are common to all versions of the integrated circuit device 10 that are manufactured using the process 20A, different versions of the integrated circuit device 10 may have different functionalities associated with different applications (e.g., shown here as Application A, Application B, and Application C) depending on the particular via configuration of a via layer of the integrated circuit device 10. Thus, the process 20 may also include performing (block 24) lithography with mask(s) for Application A (e.g., a voltage-mode driver circuit) that produces one or more via layers that will form connections that cause the circuitry formed at block 22 to operate with a first functionality (e.g., voltage-mode driver). On the other hand, the process 20 may include performing (block 26) lithography with mask(s) for Application B (e.g., a current-mode driver circuit) that produces one or more via layers that will form connections that cause the circuitry formed at block 22 to operate with a second functionality (e.g., as a current-mode driver). Further, the process 20 may include performing (block 28) lithography with mask(s) for Application C (e.g., a true differential driver circuit) that produces one or more via layers that will form connections that cause the circuitry formed at block 22 operate with a third functionality (e.g., true differential driver) associated with Application C. Specifically, performing lithography for each of these applications may include selecting via sites of the via layer to configure for either the integrated circuit device 10 for Application A, Application B, or Application C. Thus, the one or more via layer photomasks or photomasks sets are used to pattern and selectively connect components for each of the different integrated circuit devices 10 (e.g., integrated circuits for each application A, B, and C) that may be manufactured by the process 20A.

The process 20 may include performing (block 30) the certain final common lithography steps, which may include steps related to the removal of coating and modification of electrical properties.

The location of the multiple via sites or openings may be based on the various possible application functions to be performed and the components used to perform such functions. The selectable via sites may be filled (e.g., configured or selected) or remain unfilled (e.g., not selected) depending on the specific application to be performed. Thus, when the via layer is configured for Application A by selecting particular via sites that connect the components corresponding to perform Application A, there may be via sites that remain unselected since the components connected to those via sites may not be used to perform the functions of Application A. Similarly, some of the via sites used to perform Application A may not be selected when the via layer is configured for Application B. As such, using a lithography process for each particular application (e.g., Applications A, B, and C) may be mitigated or avoided by using the configurable via layer. Thus, fewer photomasks and/or application specific integrated circuit devices 10 may be manufactured, resulting in lower manufacturing costs and more efficient integrated circuit devices 10. Upon configuring the via layer for the particular application, such as by selecting particular vias (e.g., filing via openings with metal) to interconnect components used for the particular application, the integrated circuit, or at least those vias selected, may have a static configuration.

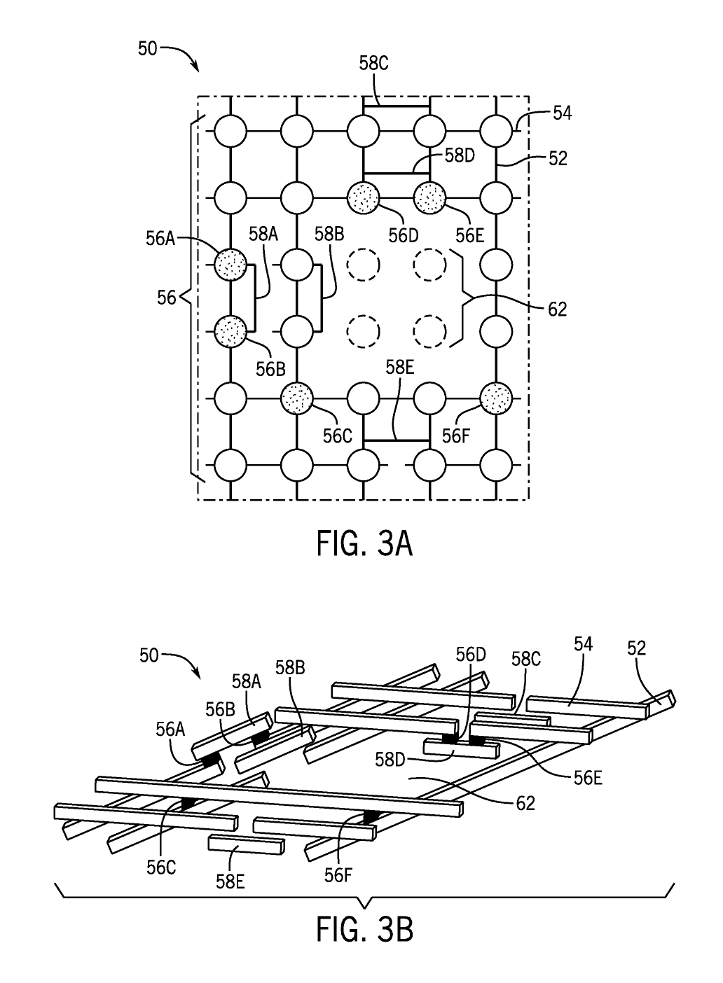

To facilitate the reuse of circuitry or components between the layers of the single integrated circuit device 10 to implement different applications, vias may be used. For example, and referring back to Applications A and B, some of the circuitry components that are used for Application A may also be used for the circuitry for Application B. Thus, these circuitry components may be reused when the via layer is configured for either Application A or Application B. To illustrate, FIG. 3, which represents a particular embodiment, depicts an integrated circuit device 10 with a via layer 50 (e.g., via layer 16 of FIG. 1) including selectable via sites 56 that may connect components and/or circuity residing on different layers of the integrated circuit device 10. Although the integrated circuit device 10 is discussed as having two layers (e.g., first circuit layer 12 and second circuit layer 14 of FIG. 1) in the current embodiment, it should be appreciated that three or more layers may be used to implement different applications or functions using the vias connections described herein. The additional via layers 50 may be used to connect components between the three or more layers.

As shown, the via layer 50 may include a vertical segment layer 52 (as indicated by the vertical bold lines) of metal segments and a horizontal segment layer 54 (as indicated by the horizontal and relatively thinner lines) of metal segments. The vertical segment layer 52 and the horizontal segment layer 54 may each include selectable via sites 56, which may be used to interconnect segments of the vertical and horizontal segment layers 52 and 54. In some implementations, jumpers 58 may be selectively placed vertically or horizontally along the segments of the vertical segment layer 52 and the horizontal segment layer 54 to facilitate vias connections that may otherwise be disconnected. For example, the jumpers 58 may facilitate in connecting or disconnecting via sites 56 to connect or disconnect segments. As such, the via layer 50 may be reconfigured using the jumpers 58. The circuitry components on the first circuit layer 12 and the second circuit layer 14 that are connected to a respective segment of the via layer 50 (e.g., vertical segment layer 52 and the horizontal segment layer 54) may be connected or disconnected using the via sites 56 to form a circuit for a particular application.

To illustrate, selected vias (e.g., via sites filled with metal to create interconnection) are indicated by darkened selectable via sites 56 in the depicted embodiments. As shown, jumpers 58A, B, C, D, and E create a link between selectable via sites 56 that are on the same segment layer. For example, selectable via sites 56A and 56B may reside on separate segments of the vertical segment layer 52. Accordingly, jumper 58A may connect these two segments, such that when the selectable via sites 56A and 56B are selected, components and/or circuitry on their respective segments may be connected. Similarly, jumpers 58B, 58C, 58D, and 58E may connect selectable via sites 56, such that the jumpers 58 allow a connection to be made between segments of the vertical segment layer 52 or the horizontal segment layer 54, and between the vertical segment layer 52 and the horizontal segment layer 54 when their respective selectable via sites 56 are selected.

Although jumpers 58 may be placed between segments of the vertical segment layer 52 and the horizontal segment layer 54, some of the selectable via sites 56 may not be selected, as indicated by the white selectable via sites 56. In such instances, segments of vertical segment layer 52 and the horizontal segment layer 54 may not be connected. For example, jumper 58E may connect two segments of the horizontal segment layer 54 when the selectable via sites 56 are selected. Since these selectable via sites 56 are not selected, the segments may not be connected and thus, the components or circuitry on those segments may not be interconnected. Moreover, in some implementations, non-selectable via sites 62 may exist on the vertical segment layer 52 and/or the horizontal segment layer 54. The non-selectable via sites 62 may include areas that may not be suitable for a selectable via site 56. These areas may not be adjacent or parallel to components on the other layers, may include jumper connections, or that may include base circuitry or application specific circuitry that is not compatible for use for a different application.

To further illustrate the connections between the layers 52 and 54 using jumpers 58 and/or selectable via sites 56, FIG. 3 depicts a three dimensional (3-D) diagram of the via layer 50 of FIG. 2. As shown, segments of the vertical segment layer 52 and the horizontal segment layer 54 may be connected using jumpers 58 and selectable via sites 56 connections that correspond to FIG. 2. For example, selectable via sites 56A and 56B may reside on separate segments of the first layer 52. Accordingly, jumper 58A may connect these two segments, such that when the selectable via sites 56A and 56B are selected, components and/or circuitry on their respective layer segments may be connected. Also corresponding to FIG. 2, jumpers 58B, 58C, 58D, and 58E may connect selectable via sites 56, such that jumpers 58 allow a connection to be made between segments of the vertical segment layer 52 and the horizontal segment layer 54, and between the vertical segment layer 52 and horizontal segment layer 54 when their respective selectable via sites 56 are selected. These segments of layers 52 and 54 may include components or circuitry that may be connected to perform specific functions.

Specifically, the selectable via sites 56 that are selected may be active sites used to short the path between the vertical segment layer 52 and the horizontal segment layer 54. In this manner, the components on the portion of the layer connected to the via site 56 may be used or unused depending on the selection of the selectable via site 56. Thus, using vias may reduce the number of application specific circuits and layers, and correspondingly, reduce the number of photomasks used to produce each of the layers. Moreover, since circuit components between layers of the integrated circuit device 10 may be reused, vias may reduce the amount of circuitry and silicon area that may otherwise be used for each application.

As previously discussed, the integrated circuit device 10 may include an input output driver circuit. A driver circuit for multiple standards (e.g., voltage-mode driver, current-mode driver, etc.) may each be formed using separate photomasks. However, both these driver circuits may include common components. As will be described herein, rather than forming separate driver circuits, the single via layer 50 may be used to connect the redundant components of circuitry between layers of the integrated circuit device 10 to configure circuitry and implement the various driver circuit standards in the integrated circuit device 10. As used herein, redundant components may refer to one or more common components to the circuit resulting from a first configuration, such as a voltage-mode driver configuration, and the circuit resulting from a different configuration, such as a current-mode driver configuration. Additionally or alternatively to selectable via sites 56, multiplexers may be used to dynamically configure and select specific circuitry to implement any of the driver circuit standards.

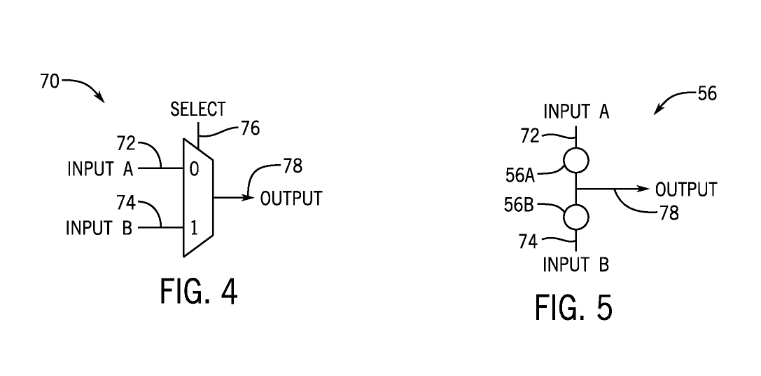

To illustrate, FIG. 4 depicts a multiplexer 70 that may be dynamically configured and programmed to select a driver circuit. As shown, the multiplexer 70 may include two input ports, input A 72 and input B 74, one control select signal, select 76, and an output port, output 78. A control select signal at select 76 may be used to control which input port (e.g., input A 72 or input B 74) is utilized to select one of the driver circuits (e.g., voltage-mode driver circuit, the current-mode driver circuit, or differential driver circuit) or components of the driver circuit. For example, input A 72 may be used for the output 78 when the control signal at select 76 has a value of “0.” On the other hand, input B 74 may be used for the output 78 when the control signal at select 76 has a value of “1.” Thus, to implement the voltage-mode driver circuit, the current-mode driver circuit, the differential driver circuit, or components of these particular driver circuits, input A 72 or input B 74 may be selectively enabled using select 76.

In other embodiments, vias may be used in conjunction with or in place of multiplexer 70 of FIG. 4. To illustrate, FIG. 5 depicts a static configuration of via sites 56 (e.g., selectable via sites 56 of FIG. 3) that may be selected (e.g., via openings filled with metal to create interconnection) to implement a particular application. As shown, the via site 56A may connect an input A 72 to output an output 78 when selected, or via site 56B may connect an input B 74 to output a different result of output 78 when selected. Circuitry and components of input A 72 connected to via site 56A may be enabled for use upon selection of the via site 56A. Similarly, circuitry or components of input B 74 that are connected to via site 56B, may be enabled for use upon selection or activation of the via site 56B.

Thus, by selecting or activating particular via sites 56A or 56B, the circuitry of the selected inputs (e.g., input A 72 or input B 74) may be included in the integrated circuit device 10 to be used for a particular driver circuit. Via sites 56 may be selected or unselected (e.g., remain unfilled) based on the application to be executed and the circuitry used for the particular application. As previously mentioned, via sites 56 of the via layer 50 may be selected to configure the integrated circuit device 10 by connecting redundant circuitry between the various layers of the integrated circuit device 10. In this manner, producing additional mask layers associated with each application specific integrated circuit device 10 and/or circuitry for a particular application of the integrated circuit device 10 may be mitigated.

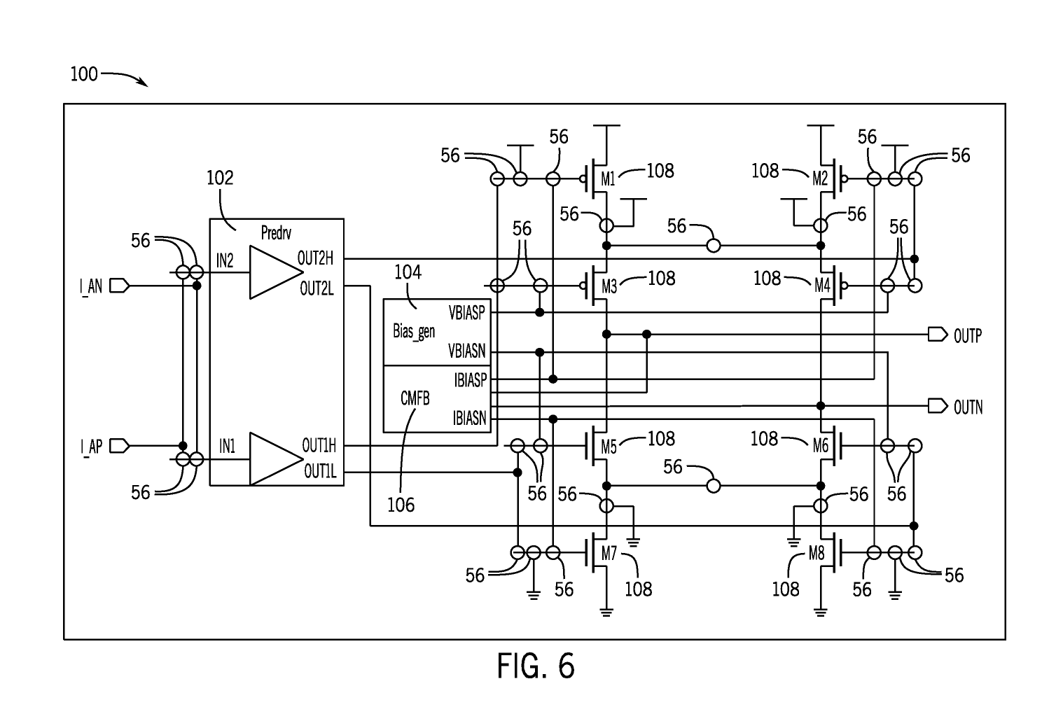

To illustrate, FIG. 6 shows configurable I/O driver circuit 100 that may be configured using via sites 56 of the via layer 50, to facilitate the same single circuitry to function for a particular driver standard. For example, the circuit may be configured for one driver standard (e.g., current-mode differential driver) or another driver standard (e.g., two independent voltage-mode single ended drivers) to support different technologies by selecting specific via sites 56. The circuitry may include a series of components, such as a pre-driver circuit 102, a current bias generator 104 (e.g., biasing circuit), and a common mode feedback circuit (CMFB) 106. Moreover, the configurable circuit may include a series of metal-oxide semiconductor field-effect transistors (MOSFET) (e.g., M1-M8). Each of the transistors may act as switches to connect and disconnect components and electrical signals when a particular voltage is applied to their respective gates.

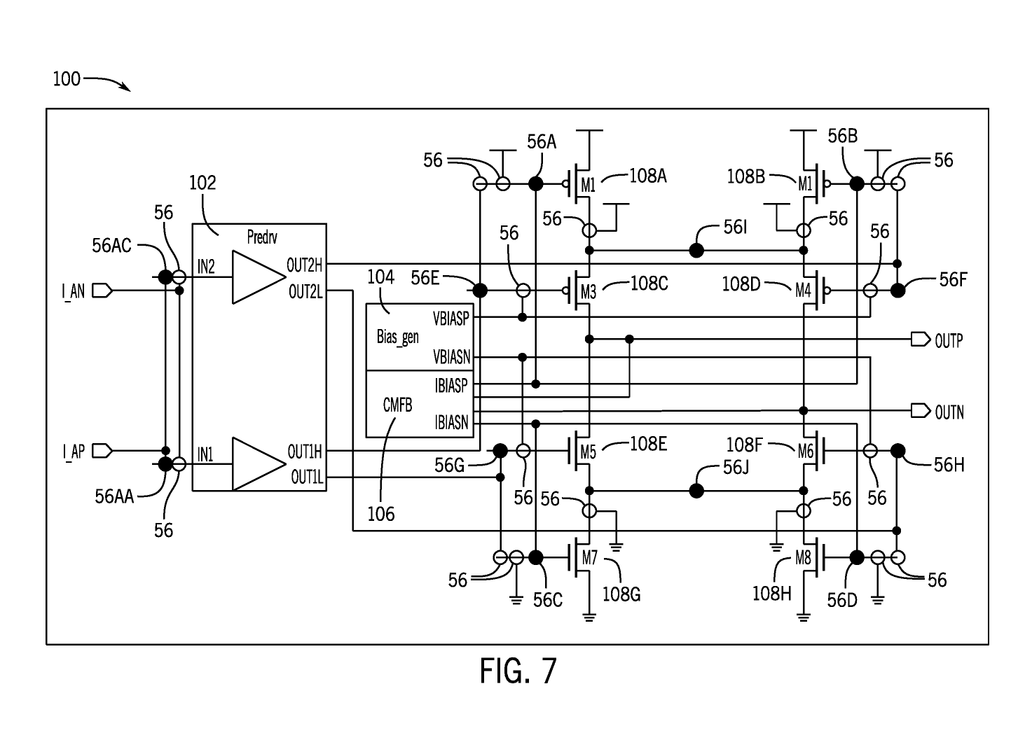

The configurable I/O driver circuit 100 may be configured to support various power supply values, drive strengths, and/or drive current based on the driver standard. These different configurations may be provided by selectively enabling one or more via sites 56 on one or more via layers 50 to connect or disconnect components connected to segments of the respective via site 56. As previously mentioned, via sites 56 may be selected or enabled by filling the via opening of the via site 56 with metal to interconnect the components connected to the respective via site 56. As shown, multiple vias sites 56 are connected to the various components of the driver circuit 100, and thus, may be enabled to implement a particular driver circuit, as will be discussed in FIGS. 7-10.

FIG. 7 illustrates the configurable I/O driver circuit 100 of FIG. 6 configured as a current-mode differential driver. As shown, some via sites 56 may be selected, as indicated by the dark shading, to interconnect the components between the two layers 52, 54. For example, portions of the depicted circuit 100 may reside on different layers (e.g., layer 52 and 54) and as such, via sites 56 may be used to interconnect these components to implement the current-mode differential driver circuit. The current-mode differential driver circuit may include, but is not limited to, low-voltage differential signaling (LVDS), Sub-LVDS, and Bus-LVDS.

As shown, via sites 56A-56J, 56AA, and 56AC are selected, connecting circuitry components to implement a pair of current-mode differential drivers. Specifically, via sites 561 and 56J may connect two drivers together to create two differential drivers. Selected via sites 56A-56J may switch transistors 108A-108H (e.g., M1-M8) to “ON.” The gate of transistors 108C-108F corresponding to M3-M6 may be connected to the pre-driver circuit 102 when via sites 56E-56H are enabled. Enabling transistors 108A-108D (e.g., M1-M4), by selecting via site 56A-56D, may allow creating a current mirror on the top half and bottom half of the circuit 100 respectively. Selected via sites 56A-D may connect transistors 108A, 108B, 108G, and 108H (e.g., M1, M2, M7, and M8) to the biasing circuit 104. The biasing circuit 104 may include a common mode feedback, such as for a LVDS standard. The common mode feedback may ensure that the common mode of the output signal is biased within a specified range.

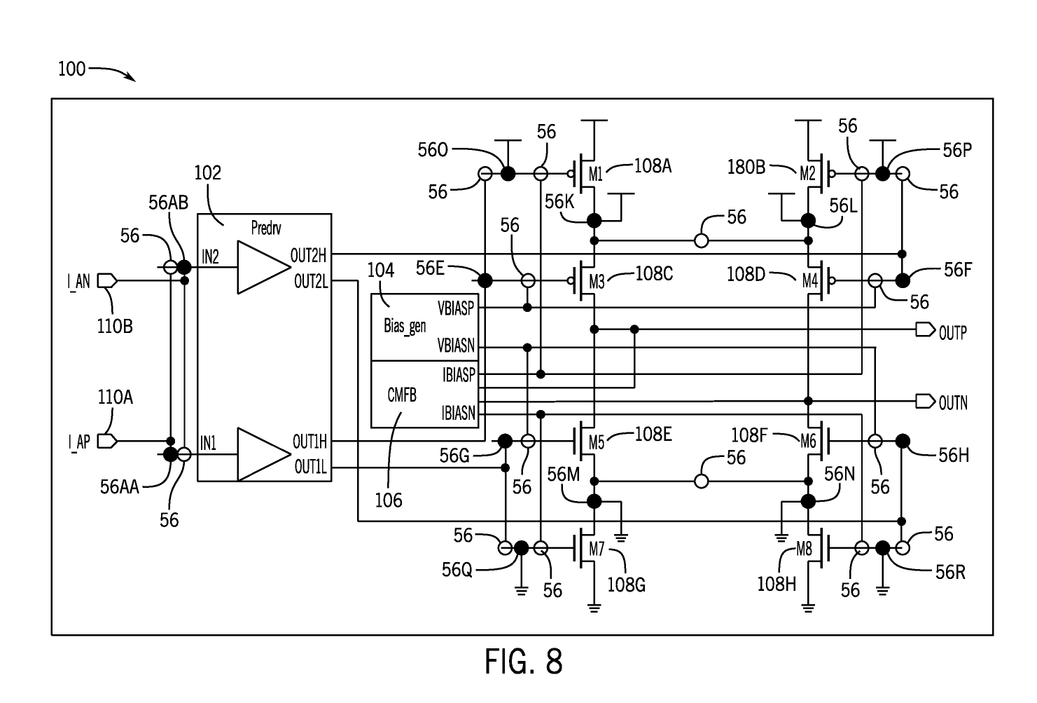

To support voltage-mode drivers, FIG. 8 illustrates the configurable I/O driver circuit 100 of FIG. 6 configured as two independent single-ended voltage-mode drivers. For example, the single-ended voltage-mode drivers may include, but are not limited to, Double Data Rate 2 (DDR2), Double Data Rate 3 (DDR3), Double Data Rate 4 (DDR4), Low-Power Double Data Rate 3 (LPDD3), Reduced Latency Dynamic Random-Access Memory (DRAM) 3 (RLDRAM3), Open NAND Flash Interface (ONFI), and Low-Voltage Complementary Metal Oxide Semiconductor (LVCMOS). As shown, via sites 56E-56H, 56K-56R, 56AA, and 56AB are selected, connecting circuitry components to implement the two independent single-ended voltage-mode drivers. In the depicted configuration for the single-ended voltage-mode drivers, transistors 108A-108D (e.g., M1, M2, M7, and M8) may be unused, and thus, may be tied to ground (e.g., NMOS transistors 108G-108H tied to Vₛₛ ground) to switch them to “OFF,” as indicated by selected via sites 560-56S.

Transistors 108C-108F (e.g., M3-M6) may be used to create the main voltage-mode driver, and as such, may be connected to supply and ground using selected via sites 56K-56N. The gate of transistor 108C and 108E (e.g., M3 and M5) may be connected to input signal (I_AP) 110A of the pre-driver circuit 102, such as by via site 56AA. This may allow transistor 108C and 108E to form a voltage-mode driver that is driving the signal from I_AP. On the other hand, the gates of transistor 108D and 108F (e.g., M4 and M6) may be connected to input (I_AN) 110B of the pre-driver circuit 102, such as by via site 56AB. This may allow transistor 108D and 108F to form a voltage-mode driver that is driving the signal from source I_AP. These input signals 110A and 110B may be transmitted from two independent sources. However, some technologies may supply a greater voltage to the single-ended drivers than may be tolerated by the single-ended drivers.

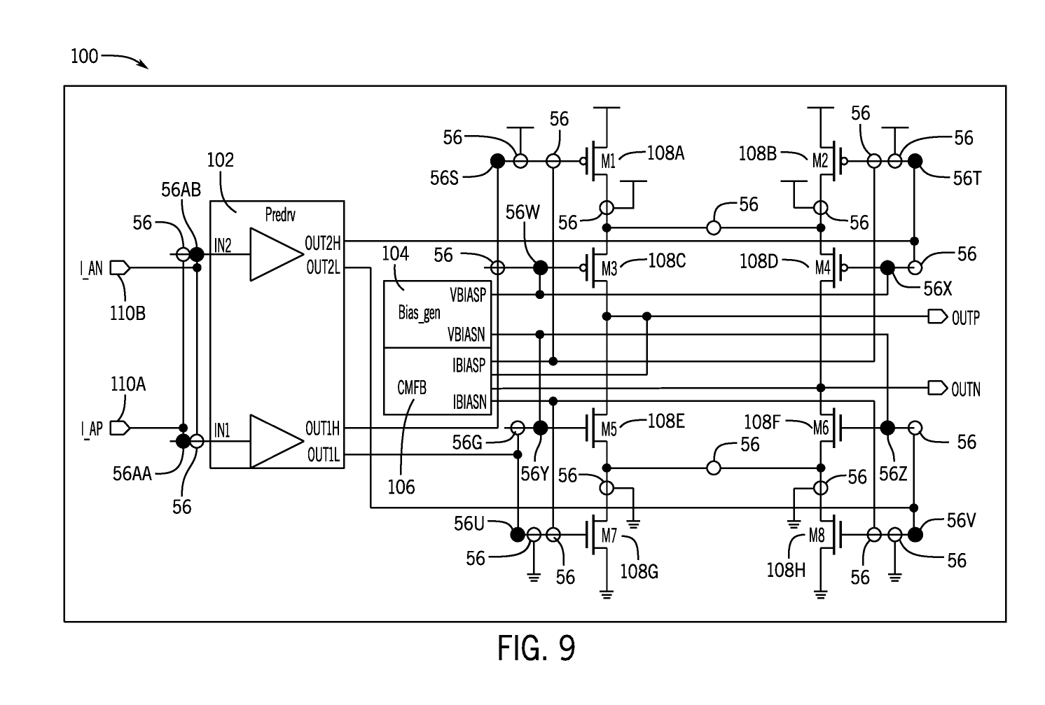

FIG. 9 illustrates the configurable I/O driver circuit 100 of FIG. 6 configured as two independent single-ended voltage-mode drivers with voltage overstress protection. In some applications, the configurable I/O driver circuit 100 may be overpowered, causing transistors 108 to be powered beyond their defined range of tolerance. For example, the transistors 108 may be set to tolerate 1.8V of power but the application for which they are used may supply 3.3V. In such circumstances, and in the depicted embodiment, the transistors 108 may be protected with a biasing level. This may allow the transistors 108 to drive signals at a high voltage (e.g., 3.3V) without long term damage.

As shown, transistors 108A, 108B, 108G, and 108H (e.g., M1, M2, M7, and M8), may be connected to the pre-driver circuit 102 using via sites 56S, 56T, 56U, and 56V respectively. Transistors 108A and 108G may be connected to a source of the pre-driver circuit 102 that receives signals from input signal (I_AP) 110B, while 108B and 108H may be connected to another source that receives signals from input signal (I_AN) 110A. Thus, transistors 108A and 108G may receive input signals independently from transistors 108B and 108H.

To protect the transistors 108A, 108B, 108G, and 108H from receiving a high voltage, transistors 108C-108F (e.g., M3-M6) may be connected to the biasing circuit 104. The biasing circuit 104 may be used to allow a lower level of voltage (e.g., voltage within tolerance) to the gates to bias transistors 108C-108F. Transistors 108C-108F may serve as protection transistors for transistors 108A, 108B, 108G, and 108H.

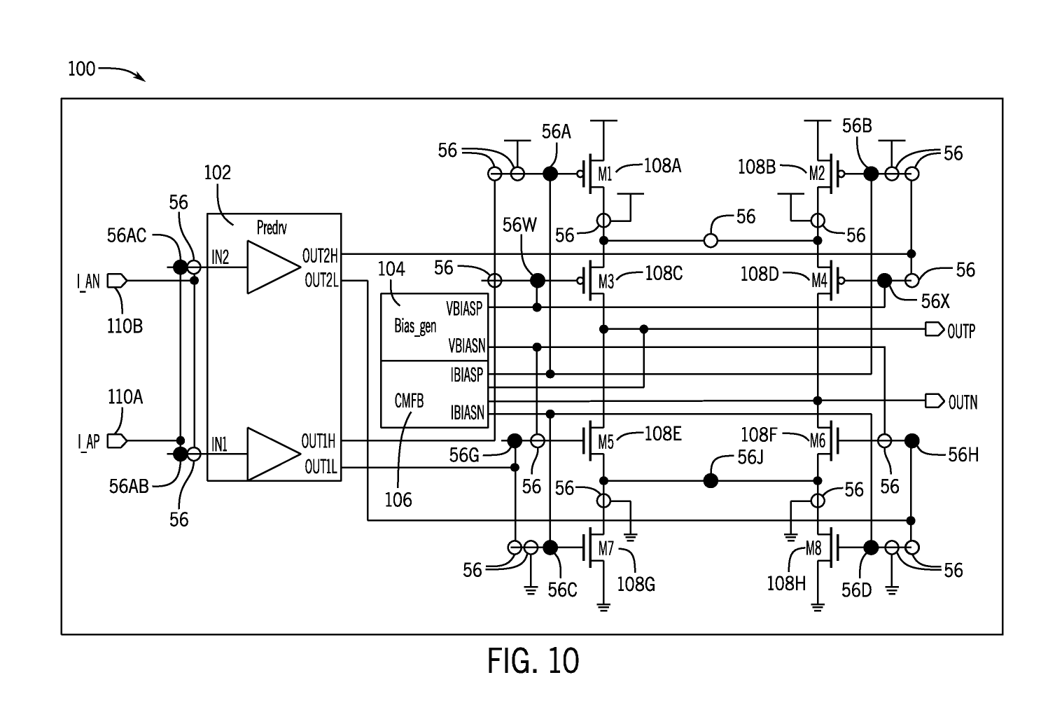

FIG. 10 illustrates the configurable I/O driver circuit 100 of FIG. 6 configured as a pair of differential current-mode drain drivers. As shown, via sites 56A-56D, 56G, 56H, 56W, 56X, 56AA, and 56AC are selected, connecting circuitry components to implement the pair of differential current-mode drain drivers. In the depicted embodiment, the PMOS transistors 108, which includes transistors 108A-108D, are connected to the biasing circuit 104. Specifically, 108C and 108D are connected to VBIASP of the biasing circuit 104 while and 108A and 108B are connected IBIASP of the biasing circuit 104. The top half of the circuit 100 serves as an active load, which may be calibrated. For example, the output impedance may be calibrated and matched to a channel that is driving the circuit 100. The lower half of the circuit 100 includes transistors 108E and 108F that may act as switches. Transistors 108E and 108F are connected to pre-driver circuit 102 and may receive signals from the pre-driver circuit 102 to switch “ON” and “OFF.” Transistors 108G and 108H, which are connected by selected via sites 56C and 56D, function as a current mirror. The configuration depicted here is another current-mode differential driver that can support standards such as, but not limited to, transition-minimized differential signaling (TMDS), and CIVIL (current-mode logic). As such, different driver circuit standards may be implemented using the same single configurable I/O driver circuit 100 that includes the via layer 50. Specifically, the particular driver circuit may be implemented by selecting specific via sites 56 of the via layer 50.

Moreover, while the method operations have been described in a specific order, it should be understood that other operations may be performed in between described operations, described operations may be adjusted so that they occur at slightly different times or described operations may be distributed in a system which allows the occurrence of the processing operations at various intervals associated with the processing, as long as the processing of overlying operations is performed as desired.

While the embodiments set forth in the present disclosure may be susceptible to various modifications and alternative forms, specific embodiments have been shown by way of example in the drawings and have been described in detail herein. However, it may be understood that the disclosure is not intended to be limited to the particular forms disclosed. The disclosure is to cover all modifications, equivalents, and alternatives falling within the spirit and scope of the disclosure as defined by the following appended claims. In addition, the techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function]. . . ” or “step for [perform]ing [a function]. . . ”, it is intended that such elements are to be interpreted under 35 U.S.C. 112(f). However, for any claims containing elements designated in any other manner, it is intended that such elements are not to be interpreted under 35 U.S.C. 112(f).

What is claimed is:

1. An integrated circuit device comprising:
a driver circuit; and
a via layer that, based on a via configuration of the via layer, causes the driver circuit of the integrated circuit device to function as:
one or more single-ended voltage-mode driver circuits in a first via configuration;
a current-mode driver in a second via configuration;
a differential driver circuit in a third via configuration; and
a high voltage overstress protection circuit in a fourth via configuration.

2. The integrated circuit device of claim 1, wherein the driver circuit comprises a pre-driver, a voltage and current bias generator, a common-mode feedback circuit, a plurality of transistors, or a combination thereof.

3. The integrated circuit device of claim 2, wherein the integrated circuit device is configured to operate using multiple power supply values, wherein the multiple power supply values comprise at least a voltage greater than a voltage threshold for the plurality of transistors.

4. The integrated circuit device of claim 1, wherein the first via configuration comprises a first configuration of via sites in the via layer, the second via configuration comprises a second configuration of the via sites in the via layer, the third via configuration comprises a third configuration of the via sites in the via layer, and the fourth via configuration comprises a fourth configuration of the via sites in the via layer, and wherein the first via configuration of via sites, the second via configuration of via sites, the third via configuration of the via sites, and the fourth via configuration of the via sites, are different.

5. The integrated circuit device of claim 1, wherein the via layer comprises a plurality of vertical segments, a plurality of horizontal segments, or a combination thereof.

6. The integrated circuit device of claim 5, wherein the plurality of vertical segments, the plurality of horizontal segments, or a combination thereof, are connected using one or more jumpers.

7. The integrated circuit device of claim 6, wherein the jumpers allow reconfiguring the via layer, and wherein the reconfiguring results in connecting or disconnecting a pre-driver of the driver circuit, a voltage and current bias generator of the driver circuit, a common-mode feedback circuit of the driver circuit, a plurality of transistors of the driver circuit, or a combination thereof, based on the reconfiguration of the via layer.

8. The integrated circuit device of claim 1, wherein the via layer is associated with a single photomask.

9. The integrated circuit device of claim 1, wherein the integrated circuit device comprises a multiplexer circuit, wherein the multiplexer circuit allows a dynamic configuration of the first via configuration, the second via configuration, the third via configuration, or the fourth via configuration.

10. A method of manufacturing an integrated circuit comprising:
forming circuitry using a first one or more masks; and
forming vias using a second one or more masks to produce one of a plurality of via configurations, wherein a first via configuration of the plurality of via configurations causes a portion of the circuitry to operate as a single-ended voltage-mode driver circuit, wherein a second via configuration of the plurality of via configurations causes the portion of the circuitry to operate as a current-mode driver circuit, and wherein a third via configuration of the plurality of via configurations causes the portion of the circuitry to operate as a differential driver circuit.

11. The method of claim 10, comprising a fourth via configuration of the plurality of via configurations that causes the portion of the circuitry to provide voltage overstress protection.

12. The method of claim 10, wherein the circuitry, when used with any of the first via configuration, the second via configuration, and the third via configuration, comprises at least one redundant component, wherein the redundant component is a common component to the circuit resulting from the first via configuration, the circuit resulting from the second via configuration, and the circuit resulting from the third via configuration.

13. The method of claim 10, wherein the second one or more masks for the vias replaces at least one or more masks associated with a single-ended voltage-mode driver circuit, a current-mode driver circuit, a differential driver, or a combination thereof

14. A configurable circuit, comprising:
a circuit comprising a pre-driver, a voltage and current bias generator, a common-mode feedback circuit, a plurality of transistors, or a combination thereof; and
a plurality of vias connected to at least a portion of the circuit to implement:
a single-ended voltage-mode driver circuit in a first configuration;
a current-mode driver in a second configuration;
a differential driver circuit in a third configuration; and
a high voltage overstress protection circuit in a fourth configuration.

15. The configurable circuit of claim 14, where the plurality of vias turn the plurality of transistors to an ON mode in the second configuration, wherein the ON mode causes the configurable circuit to form at least one current mirror.

16. The configurable circuit of claim 14, wherein the common-mode feedback circuit causes a common mode of an output signal of the configurable circuit to be biased within a specified range.

17. The configurable circuit of claim 14, where the plurality of vias connect two differential drivers in the second configuration.

18. The configurable circuit of claim 14, where the plurality of vias turn at least one of the plurality of transistors to an ON mode in the first configuration, wherein the ON mode causes the configurable circuit to form the voltage-mode driver driving inputs from two independent sources of the pre-driver.

19. The configurable circuit of claim 14, where the plurality of vias turn at least a first transistor of the plurality of transistors and a second transistor of the plurality of transistors to an ON mode in the fourth configuration, wherein the ON mode causes the first transistor to connect to a lower voltage input and the second transistor to connect to a higher voltage input, wherein the lower voltage input is a voltage within a defined tolerance for the plurality of transistors, and wherein the higher voltage input is a voltage above the defined tolerance for the plurality of transistors.

20. The configurable circuit of claim 19, wherein the voltage and current bias generator lowers the level of voltage to the first transistor.
